(19) United States
(12) Patent Application Publication
(10) Pub. No.: US 2020/0027731 A1
(43) Pub. Date: Jan. 23, 2020

(54) FILM FORMING METHOD AND MANUFACTURING METHOD OF SEMICONDUCTOR DEVICE

(71) Applicants: Tatsuji NAGAOKA, Nagakute-shi (JP); Hiroyuki NISHINAKA, Kyoto-shi (JP); Masahiro YOSHIMOTO, Kyoto-shi (JP)

(72) Inventors: Tatsuji NAGAOKA, Nagakute-shi (JP); Hiroyuki NISHINAKA, Kyoto-shi (JP); Masahiro YOSHIMOTO, Kyoto-shi (JP)

(73) Assignees: TOYOTA JIDOSHA KABUSHIKI KAISHA, Toyota-shi (JP); NATIONAL UNIVERSITY CORPORATION KYOTO INSTITUTE OF TECHNOLOGY, Kyoto-shi (JP)

(21) Appl. No.: 16/512,447

(22) Filed: Jul. 16, 2019

(30) Foreign Application Priority Data
Jul. 17, 2018 (JP) 2018-134347

(51) Int. Cl. H01L 21/02; C23C 16/40; C30B 29/16; C30B 25/20

(52) U.S. Cl. CPC H01L 21/02565; H01L 21/02628; H01L 21/02598; C30B 25/20; C23C 16/40; C30B 29/16; H01L 21/02576

(57) ABSTRACT

A film forming method of forming a gallium oxide film doped with tin on a substrate is disclosed herein. The film forming method may include supplying mist of a solution to a surface of the substrate while heating the substrate, wherein a gallium compound and a tin chloride (IV) pentahydrate are dissolved in the solution.

### CROSS-REFERENCE TO RELATED APPLICATION

This application claims priority to Japanese Patent Application No. 2018-134347 filed on Jul. 17, 2018, the contents of which are hereby incorporated by reference into the present application.

### TECHNICAL FIELD

A technology disclosed herein relates to a technology of forming a film on a substrate.

### BACKGROUND

Japanese Patent Application Publication No. 2013-028480 describes a technology of forming a gallium oxide film. In this technology, mist of a solution in which a gallium compound and a tin(II) compound are dissolved is supplied to a surface of a substrate while heating the substrate. According to this technology, a gallium oxide film in which tin has been added can be grown on the surface of the substrate.

### SUMMARY

Tin can have oxidation numbers II and IV. Tetravalent tin (hereinafter termed tin(IV)) functions as a donor in gallium oxide, whereas divalent tin (hereinafter termed tin(II)) does not function as a donor in gallium oxide. Therefore, in Japanese Patent Application Publication No. 2013-028480, hydrochloric acid and hydrogen peroxide are added to the solution in which the gallium compound and the tin(II) compound are dissolved to convert the tin(II) compound into a tin(IV) compound. However, when a gallium oxide film is grown on the surface of the substrate by mist generated from the solution in which hydrochloric acid and hydrogen peroxide have been added, the solution causes a decrease in growth rate of the gallium oxide film. Therefore, the disclosure herein proposes a film forming method that is capable of forming a gallium oxide film doped with tin at a higher growth rate.

In a film forming method disclosed herein, a gallium oxide film doped with tin is formed on a substrate. This film forming method may comprise supplying mist of a solution to a surface of the substrate while heating the substrate. A gallium compound and a tin(IV) chloride pentahydrate may be dissolved in the solution.

When the mist of the solution (i.e., the solution in which the gallium compound and the tin(IV) chloride pentahydrate are dissolved) is supplied to the surface of the substrate, the mist adheres to the surface of the substrate. The mist that adheres to the surface of the heated substrate chemically reacts on the substrate. Consequently, a gallium oxide film in which tin(IV) has been added is generated on the surface of the substrate. Tin(IV) functions as a donor in the gallium oxide film. Therefore, according to this film forming method, the gallium oxide film doped with tin can be formed. Moreover, in this film forming method, tin(IV), which functions as a donor, is incorporated in the gallium oxide film without adding hydrochloric acid or hydrogen peroxide solution to the solution. Therefore, according to this film forming method, the gallium oxide film can be grown at a high growth rate.

### BRIEF DESCRIPTION OF DRAWING

FIG. 1 is a configuration diagram of a film forming device 10.

### DETAILED DESCRIPTION

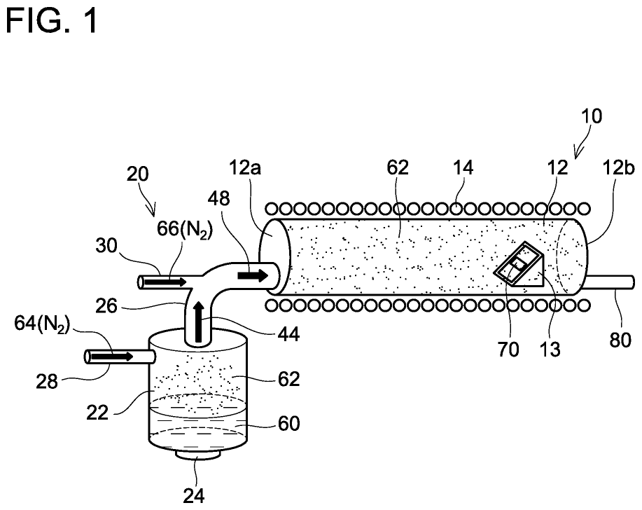

A film forming device 10 shown in FIG. 1 is a device configured to form a gallium oxide film on a substrate 70. The film forming device 10 includes a furnace 12 in which the substrate 70 is placed, a heater 14 configured to heat the furnace 12, a mist supply device 20 connected to the furnace 12, and a discharge pipe 80 connected to the furnace 12.

A specific configuration of the furnace 12 is not limited particularly. As an example, the furnace 12 shown in FIG. 1 is a tubular furnace that extends from an upstream end 12a to a downstream end 12b. A cross section of the furnace 12, which is taken perpendicular to a longitudinal direction of the furnace 12, is circular. For example, a diameter of the furnace 12 may be set to approximately 40 mm. It should be noted that the cross section of the furnace 12 is not limited to a circular shape. The furnace 12 has its upstream end 12a connected to the mist supply device 20. The furnace 12 has its downstream end 12b connected to the discharge pipe 80.

In the furnace 12, a substrate stage 13 for supporting the substrate 70 is provided. The substrate stage 13 is configured to allow the substrate 70 to be tilted relative to the longitudinal direction of the furnace 12. The substrate 70 supported by the substrate stage 13 is supported in an orientation that exposes a surface of the substrate 70 to mist flowing in the furnace 12 from the upstream end 12a toward the downstream end 12b.

The heater 14 heats the furnace 12 as mentioned before. A specific configuration of the heater 14 is not limited particularly. As an example, the heater 14 shown in FIG. 1 is an electric heater and is arranged along an outer peripheral wall of the furnace 12. The heater 14 thus heats the outer peripheral wall of the furnace 12 and the substrate 70 in the furnace 12 is thereby heated.

The mist supply device 20 supplies, into the furnace 12, mist of a solution that includes a raw material of a gallium oxide film. A specific configuration of the mist supply device 20 is not limited particularly. As an example, the mist supply device 20 shown in FIG. 1 includes a container 22 that accommodates a solution 60, an ultrasonic transducer 24 provided at the container 22, a mist supply path 26 that connects the container 22 and the furnace 12, a carrier gas introduction path 28 connected to the container 22, and a diluent gas introduction path 30 connected to the mist supply path 26. The carrier gas introduction path 28 supplies carrier gas 64 to the container 22. The diluent gas introduction path 30 supplies diluent gas 66 to the mist supply path 26. The ultrasonic transducer 24 applies ultrasonic vibrations to the solution 60 in the container 22 to generate mist 62 of the solution 60.

The discharge pipe 80 is connected to the downstream end 12b of the furnace 12. The mist 62 supplied into the furnace 12 by the mist supply device 20 flows through the furnace 12 to the downstream end 12b and is then discharged to an outside of the furnace 12 through the discharge pipe 80.

### First Embodiment

Next, a film forming method using the film forming device 10 will be described. In a first embodiment, a substrate constituted of β-gallium oxide (β-Ga₂O₃) single crystal having its (010) crystal plane exposed at a surface thereof is used as the substrate 70. Moreover, in the first embodiment, a β-gallium oxide film is formed on the surface of the substrate 70. Moreover, in the first embodiment, an aqueous solution in which gallium(III) chloride (GaCl₃Ga₂Cl₆) and a tin(IV) chloride pentahydrate (SnCl₄·5H₂O) are dissolved is used as the solution 60. In the solution 60, gallium(III) chloride is dissolved at a concentration of 0.5 mol/L and the tin(IV) chloride pentahydrate is dissolved at a concentration of 5×10⁻⁶ mol/L. Moreover, in the first embodiment, nitrogen gas is used as the carrier gas 64 and nitrogen gas is used as the diluent gas 66.

As shown in FIG. 1, firstly, the substrate 70 is placed on the substrate stage 13 in the furnace 12. Here, the substrate 70 is placed on the substrate stage 13 in an orientation that allows a (010) crystal plane of the substrate 70 to be an upper surface (a surface to be exposed to the mist 62). Next, the substrate 70 is heated by the heater 14. Here, a temperature of the substrate 70 is controlled to be at approximately 750 degrees Celsius. When the temperature of the substrate 70 is stabilized, the mist supply device 20 is activated. In other words, the ultrasonic transducer 24 is activated to generate the mist 62 of the solution 60 in the container 22. At the same time, the carrier gas 64 is introduced into the container 22 from the carrier gas introduction path 28 and the diluent gas 66 is introduced into the mist supply path 26 from the diluent gas introduction path 30. Here, a total flow rate of the carrier gas 64 and the diluent gas 66 is set to approximately 5 L/min. The carrier gas 64 passes through the container 22 and flows into the mist supply path 26 as shown by an arrow 44. At this time, the mist 62 in the container 22 flows into the mist supply path 26 together with the carrier gas 64. Moreover, the diluent gas 66 is mixed with the mist 62 in the mist supply path 26. The mist 62 is thereby diluted. The mist 62 flows through the mist supply path 26 to a downstream side together with the nitrogen gas (i.e., the carrier gas 64 and the diluent gas 66) and flows from the mist supply path 26 into the furnace 12 as shown by an arrow 48. In the furnace 12, the mist 62 flows toward the downstream end 12b together with the nitrogen gas and is discharged to the discharge pipe 80.

A part of the mist 62 flowing in the furnace 12 adheres to the surface of the heated substrate 70. When this happens, the mist 62 (i.e., the solution 60) chemically reacts on the substrate 70. Consequently, β-gallium oxide (β-Ga₂O₃) is generated on the substrate 70. Since the mist 62 is continuously supplied to the surface of the substrate 70, a β-gallium oxide film is grown on the surface of the substrate 70. According to this film forming method, a high-quality, single-crystal β-gallium oxide film is grown. Tin(IV) in the tin(IV) chloride pentahydrate is incorporated in the β-gallium oxide film as a donor. Therefore, the β-gallium oxide film doped with tin is formed. In other words, the β-gallium oxide film having a property of a semiconductor or a conductor is formed. Here, the β-gallium oxide film is grown by performing the film forming process for 30 minutes with consumption of approximately 50 ml of the solution 60. When properties of the β-gallium oxide film formed by this film forming method were measured by Hall effect measurement, a carrier density of 1.8×10¹⁸ cm⁻³ and a mobility of 77 cm²/Vsec were observed.

According to the film forming method of the first embodiment, a β-gallium oxide film with high quality can be formed. In the first embodiment, in particular, a β-gallium oxide film is homoepitaxially grown on the substrate 70 constituted of β-gallium oxide, so a β-gallium oxide film with higher quality can be formed. Moreover, due to the homoepitaxial growth, electrical conductivity of the β-gallium oxide film is easily controlled.

### Second Embodiment

Next, a film forming method of a second embodiment will be described. In the second embodiment, a substrate constituted of sapphire (Al₂O₃) is used as the substrate 70. Moreover, in the second embodiment, an α-gallium oxide film (α-Ga₂O₃) is formed on the surface of the substrate 70. Moreover, in the second embodiment, an aqueous solution in which gallium bromide (GaBr₃, Ga₂Br₆) and a tin(IV) chloride pentahydrate are dissolved is used as the solution 60. In the solution 60, gallium bromide is dissolved at a concentration of 0.1 mol/L and the tin(IV) chloride pentahydrate is dissolved at a concentration of 1×10 mol/L. Moreover, in the second embodiment, nitrogen gas is used as the carrier gas 64 and nitrogen gas is used as the diluent gas 66.

In the film forming method of the second embodiment as well, as in the first embodiment, the substrate 70 is placed on the substrate stage 13 and is heated by the heater 14. Here, the temperature of the substrate 70 is controlled to be approximately 500 degrees Celsius. When the temperature of the substrate 70 is stabilized, the mist supply device 20 is activated. In other words, the ultrasonic transducer 24 is activated, the carrier gas 64 is introduced, and the diluent gas 66 is introduced in the same way as in the first embodiment. Consequently, the mist 62 flows into the furnace 12 and a part of the mist 62 flowing in the furnace 12 adheres to the surface of the heated substrate 70. When this happens, the mist 62 (i.e., the solution 60) chemically reacts on the substrate 70. Consequently, α-gallium oxide is generated on the substrate 70. Since the mist 62 is continuously supplied to the surface of the substrate 70, an α-gallium oxide film is grown on the surface of the substrate 70. According to this film forming method, a high-quality single-crystal α-gallium oxide film is grown. Tin(V) in the tin(IV) chloride pentahydrate is incorporated in the α-gallium oxide film as a donor. Therefore, the α-gallium oxide film doped with tin is formed. In other words, the α-gallium oxide film having a property of a semiconductor or a conductor is formed.

### Third Embodiment

Next, a film forming method of a third embodiment will be described. In the third embodiment, a substrate constituted of β-gallium oxide single crystal having its (−201) crystal plane exposed at a surface thereof is used as the substrate 70. Moreover, in the third embodiment, an aqueous solution in which gallium(III) chloride and a tin(IV) chloride pentahydrate are dissolved is used as the solution 60. In the solution 60, gallium(III) chloride is dissolved at a concentration of 0.5 mol/L and the tin(IV) chloride pentahydrate is dissolved at a concentration of 5×10⁻⁶ mol/L. Moreover, in the third embodiment, nitrogen gas is used as the carrier gas 64 and nitrogen gas is used as the diluent gas 66.

In the film forming method of the third embodiment as well, as in the first embodiment, the substrate 70 is placed on the substrate stage 13. Here, the substrate 70 is placed on the substrate stage 13 in an orientation that allows a (−201) crystal plane of the substrate 70 to be an upper surface (a surface exposed to the mist 62). Next, the substrate 70 is heated by the heater 14. Here, the temperature of the substrate 70 is controlled to be at approximately 600 degrees Celsius. When the temperature of the substrate 70 is stabilized, the mist supply device 20 is activated. In other words, the ultrasonic transducer 24 is activated, the carrier gas 64 is introduced, and the diluent gas 66 is introduced in the same way as in the first embodiment. Consequently, the mist 62 flows into the furnace 12 and a part of the mist 62 flowing in the furnace 12 adheres to the surface of the heated substrate 70. When this happens, the mist 62 the solution 60) chemically reacts on the substrate 70. Consequently, ε-gallium oxide (εGa₂O₃) is generated on the substrate 70. Since the mist 62 is continuously supplied to the surface of the substrate 70, an ε-gallium oxide film is grown on the surface of the substrate 70. According to this film forming method, a high-quality, single-crystal ε-gallium oxide film is grown. Tin(IV) in the tin(IV) chloride pentahydrate is incorporated in the ε-gallium oxide film as a donor. Therefore, the ε-gallium oxide film doped with tin is formed. In other words, the ε-gallium oxide film having a property of a semiconductor or a conductor is formed.

The film forming methods of the first to third embodiments have been described. According to these film forming methods, a gallium oxide film can be doped with tin while being grown, without adding hydrochloric acid or hydrogen peroxide solution to the solution 60. Therefore, the gallium oxide film can be grown at a high growth rate. Manufacturing a semiconductor device (e.g., a diode, a transistor, or the like) with a gallium oxide film formed according to the first to third embodiments enables the semiconductor device to have good properties.

In the first to third embodiments described above, a number (concentration) of tin atoms dissolved in the solution 60 is ten times or less a number (concentration) of gallium atoms dissolved in the solution 60. According to this constitution, a gallium oxide film with high crystal quality can be formed.

Moreover, in the first to third embodiments described above, the substrate 70 is heated to 500 to 750 degrees Celsius. In the film forming step, the temperature of the substrate 70 can be controlled to 400 to 1000 degrees Celsius. Controlling the temperature as such enables a gallium oxide film to be formed more suitably.

Moreover, in each of the first to third embodiments described above, a single-crystal gallium oxide film is formed. However, an amorphous or polycrystalline gallium oxide film may be formed.

Moreover, in the first to third embodiments described above, the substrate 70 is constituted of P-gallium oxide or sapphire. However, the substrate 70 may be constituted of another material. Using the substrate 70 constituted of another material can form a gallium oxide film having a property different from those of the first to third embodiments. For example, the substrate 70 may be constituted of α-gallium oxide, γ-gallium oxide, δ-gallium oxide, ε-gallium oxide, aluminum oxide (e.g., α-aluminum oxide (α-Al₂O₃)), gallium nitride (GaN), glass, or the like. Moreover, the substrate 70 may be an insulator, a semiconductor, or a conductor.

Moreover, in each of the first to third embodiments described above, a gallium oxide film is formed on the surface of the substrate 70 (i.e., a plate-shaped member). However, a member having another shape may be used as a base and a gallium oxide film may be formed on a surface of the base.

Moreover, in the first to third embodiments described above, the gallium compound dissolved in the solution 60 is gallium(III) chloride or gallium bromide. However, another material may be used as the gallium compound to be dissolved in the solution 60. In order to form a high-quality gallium oxide film, the gallium, compound may be organic matter. Moreover, the gallium compound may be a metal complex. Alternatively, the gallium compound may be a halide. For example, gallium acetylacetonate (e.g., gallium(III) acetylacetonate (C₁₅H₂₁GaO₆)), gallium triacetate (C₆H₉GaO₆), gallium iodide (GaI₃, Ga₂I₆), or the like can be used as the gallium compound. It should be noted that gallium chloride (gallium(III) chloride, in particular) is more easily used because it is inexpensive and enables film formation with fewer residual impurities.

Moreover, in the first to third embodiments described above, the container 22 accommodates the solution 60 in which both of the gallium compound and the tin(IV) chloride pentahydrate are dissolved, the mist is generated from the solution 60 and the generated mist is supplied to the furnace 12. However, a first container that accommodates a solution in which the gallium compound is dissolved and a second container that accommodates a solution in which the tin(IV) chloride pentahydrate is dissolved may be separately provided. Then, first mist of the solution in which the gallium compound is dissolved may be generated in the first container, second mist of the solution in which the tin(IV) chloride pentahydrate is dissolved may be generated in the second container, and the first mist and the second mist may be supplied to the furnace 12.

Moreover, in the first to third embodiments described above, nitrogen is used as the carrier gas 64 and the diluent gas 66. However, another gas such as inert gas can be used as the carrier gas 64 and the diluent gas 66.

Some of the features characteristic to the disclosure herein will be listed below. It should be noted that the respective technical elements are independent of one another, and are useful solely or in combinations.

In an example of film forming method disclosed herein, supplying mist of a solution in which a gallium compound and a tin(IV) chloride pentahydrate are dissolved to a surface of a substrate may comprise generating the mist from the solution in which the gallium compound and the tin(IV) chloride pentahydrate are dissolved; and supplying the mist of the solution, in which the gallium compound and the tingle(IV) chloride pentahydrate are dissolved, to the surface of the substrate.

In another example of film forming method disclosed herein, supplying mist of a solution in which a gallium compound and a tin(IV) chloride pentahydrate are dissolved to a surface of a substrate may comprise generating mist from a solution in which the gallium compound is dissolved; generating mist from a solution in which the tin(IV) chloride pentahydrate is dissolved; and supplying the mist of the solution in which the gallium compound is dissolved and the mist of the solution in which the tin(IV) chloride pentahydrate is dissolved to the surface of the substrate.

As above, a gallium oxide film can suitably formed by any one of the method in which the mist is generated from the solution in which both the gallium compound and the tin(IV) chloride pentahydrate are dissolved and the method in which the mists are generated respectively from the solution in which the gallium compound is dissolved and the solution in which the tingle(IV) chloride pentahydrate is dissolved.

In an example of film forming method disclosed herein, the gallium oxide film may be a single-crystal film.

Forming a single-crystal gallium oxide film enables the gallium oxide film to be suitably used in a semiconductor element and the like.

In an example of film forming method disclosed herein, the gallium compound may be organic matter.

In an example of film forming method disclosed herein, the gallium compound may be a metal complex.

In an example of film forming method disclosed herein, the gallium compound may be acetylacetonate.

In an example of film forming method disclosed herein, the gallium compound may be a halide.

In an example of film forming method disclosed herein, the gallium compound may be gallium chloride.

Gallium chloride is inexpensive and less likely causes residual impurities. Therefore, it is useful as a gallium oxide film material.

In an example of film forming method disclosed herein, a number of tin atoms included in the mist of the solution in which the gallium compound and the tin(IV) chloride pentahydrate are dissolved may be ten times or less a number of gallium atoms included in the mist of the solution in which the gallium compound and the tin(IV) chloride pentahydrate are dissolved.

According to the above configuration a gallium oxide film with high crystal quality can be formed.

In an example of film forming method disclosed herein, the substrate may be constituted of gallium oxide.

In an example of film forming method disclosed herein, the substrate may be constituted of β-Ga₂O₃.

In an example of film forming method disclosed herein, the substrate may be constituted of α-Ga₂O₃.

In an example of film forming method disclosed herein, the substrate may be constituted of α-Al₂O₃.

In an example of film forming method disclosed herein, the gallium oxide film may be constituted of β-Ga₂O₃.

According to the above configuration, properties of the gallium oxide film are stable and electrical conductivity of the gallium oxide film can be easily controlled.

In an example of film forming method disclosed herein, the substrate may be heated to 400 to 1000 degrees Celsius when the gallium oxide film is formed.

According to the above configuration, a gallium oxide film with high crystal quality can be formed and electrical conductivity of the gallium oxide film can be controlled accurately.

While specific examples of the present disclosure have been described above in detail, these examples are merely illustrative and place no limitation on the scope of the patent claims. The technology described in the patent claims also encompasses various changes and modifications to the specific examples described above. The technical elements explained in the present description or drawing provide technical utility either independently or through various combinations. The present disclosure is not limited to the combinations described at the time the claims are filed. Further, the purpose of the examples illustrated by the present description or drawing is to satisfy multiple objectives simultaneously, and satisfying, any one of those objectives gives technical utility to the present disclosure.

What is claimed is:

1. A film forming method of forming a gallium oxide film doped with tin on a substrate, the film forming method comprising:
supplying mist of a solution to a surface of the substrate while heating the substrate, wherein a gallium compound and a tin(IV) chloride pentahydrate are dissolved in the solution.

2. The film forming method of claim 1, wherein
the supply of the mist to the surface of the substrate comprises:
generating the mist from the solution in which the gallium compound and the tin(IV) chloride pentahydrate are dissolved; and
supplying the mist of the solution, in which the gallium compound and the tin(IV) chloride pentahydrate are dissolved, to the surface of the substrate.

3. The film forming method of claim 1, wherein
the supply of the mist to the surface of the substrate comprises:
generating mist from a solution in which the gallium compound is dissolved;
generating mist from a solution in which the tin(IV) chloride pentahydrate is dissolved; and
supplying the mist of the solution in which the gallium compound is dissolved and the mist of the solution in which the tin(IV) chloride pentahydrate is dissolved to the surface of the substrate.

4. The film forming method of claim 1, wherein the gallium oxide film is a single-crystal film.

5. The film forming method of claim 1, wherein the gallium compound is organic matter.

6. The film forming method of claim 1, wherein the gallium compound is a metal complex.

7. The film forming method of claim 1, wherein the gallium compound is gallium acetylacetonate.

8. The film forming method of claim 1, wherein the gallium compound is a halide.

9. The film forming method of claim 1, wherein the gallium compound is gallium chloride.

10. The film forming method of claim 1, wherein a number of tin atoms included in the mist of the solution in which the gallium compound and the tin(IV) chloride pentahydrate are dissolved is ten times or less a number of gallium atoms included in the mist of the solution in Which the gallium compound and the tin(IV) chloride pentahydrate are dissolved.

11. The film forming method of claim 1, wherein the substrate is constituted of gallium oxide.

12. The film forming method of claim 11, wherein the substrate is constituted of β-Ga₂O₃.

13. The film forming method of claim 11, wherein the substrate is constituted of α-Ga₂O₃.

14. The film forming method of claim 1, wherein the substrate is constituted of α-Al₂O₃.

15. The film forming method of claim 1, wherein the gallium oxide film is constituted of β-Ga₂O₃.

16. The film forming method of claim 1, wherein the substrate is heated to 400 to 1000 degrees Celsius when the gallium oxide film is formed.

17. A manufacturing method of a semiconductor device, the manufacturing method comprising forming the gallium oxide film by the film forming method of claim 1.
